(19) United States
(12) Patent Application Publication
(10) Pub. No.: US 2007/0047687 A1
(43) Pub. Date: Mar. 1, 2007

(54) PHASE DETECTOR AND RELATED PHASE DETECTING METHOD THEREOF

(76) Inventors: Tse-Hsiang Hsu, Hsin-Chu City (TW); Shiue-Shin Liu, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/306,413

(22) Filed: Dec. 27, 2005

Related U.S. Application Data
(60) Provisional application No. 60/596,041, filed on Aug. 25, 2005.

(51) Int. Cl. H03D 3/24

(52) U.S. Cl. 375/375

(57) ABSTRACT

A phase detector for detecting a phase difference between a first signal and a second signal is disclosed. The phase detector includes: a difference determining module, a phase leading/lagging determining module, and a phase determining module. The difference determining module is used for outputting a pulse having a period in which a logic level of the first signal is different from a logic level of the second signal. The phase leading/lagging determining module is used for outputting an detection signal to identify a phase leading/lagging relationship between the first signal and the second signal. The phase determining module is coupled to the difference determining module and the phase leading/lagging determining module for combining the pulse and the detection signal to output a result signal, wherein the result signal comprises difference and leading/lagging information between the first and the second signal.

### CROSS REFERENCE TO RELATED APPLICATIONS

The application claims the benefit of U.S. Provisional Application No. 60/596,041, which was filed on Aug. 25, 2005.

### BACKGROUND

The disclosure relates to phase differences between signals, and more particularly, to a phase detector and a related phase detecting method for detecting the phase differences between signals.

A phase detector is an important device component in a signal processing system. A phase detector is used to determine the phase difference and the lead/lag relationship between two input signals. Phase detectors are widely used in many applications, such as communication, servo control, and phase lock loop.

Conventionally, a phase detector can be implemented by introducing state machine. However, a glitch of an input signal may trigger a false state transition, leading to continuous errors of the result of phase detection. Therefore, detecting the phase difference between two signals without inducing too many errors is very important for the circuit designer. A new solution for a phase detector that is robust and introduces fewer errors is in great need.

### SUMMARY OF THE INVENTION

It is therefore one of the primary objectives to provide a phase detector and a related phase detecting method for detecting the phase differences between signals, to reducing phase detection errors.

It is therefore one of the primary objectives to provide a phase detector and a related phase detecting method, wherein the errors of the phase detection result are reduced.

According to an exemplary embodiment, a phase detector for detecting a phase difference between a first signal and a second signal is disclosed. The phase detector comprises: a difference determining module, for outputting a pulse having a period in which a logic level of the first signal is different from a logic level of the second signal; a phase leading/lagging determining module, for outputting a detection signal to identify a phase leading/lagging relationship between the first signal and the second signal; and a phase determining module, for combining the pulse and the detection signal to output a result signal, wherein the result signal comprises difference and leading/lagging information between the first and the second signal.

According to another exemplary embodiment, a phase detecting method for detecting a phase difference between a first signal and a second signal is disclosed. The phase detecting method comprises: outputting a pulse having a period in which a logic level of the first signal is different from a logic level of the second signal; outputting an detection signal to identify a phase leading/lagging relationship between the first signal and the second signal; and combining the pulse and the detection signal to output a result signal, wherein the result signal comprises difference and leading/lagging information between the first and the second signal. The disclosed phase detector can detect the phase difference between signals with fewer errors.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a phase detector according to the present disclosure.

FIG. 2 is a diagram of the phase detector of a first embodiment according to the present disclosure.

FIG. 3 is a diagram of waveforms of signals shown in FIG. 2 according to the present disclosure.

FIG. 4 is a diagram of the phase detector of a second embodiment according to the present disclosure.

FIG. 5 is a diagram of waveforms of signals shown in FIG. 4 according to the present disclosure.

FIG. 6 is a diagram of the phase detector of a third embodiment.

FIG. 7 is a diagram of a phase detector of a fourth embodiment.

FIG. 8 is a diagram of a phase detector of a fifth embodiment.

FIG. 9 is a diagram of waveforms where one of the input signals has glitches.

FIG. 10 is a diagram of waveforms where the other input signals have glitches.

### DETAILED DESCRIPTION

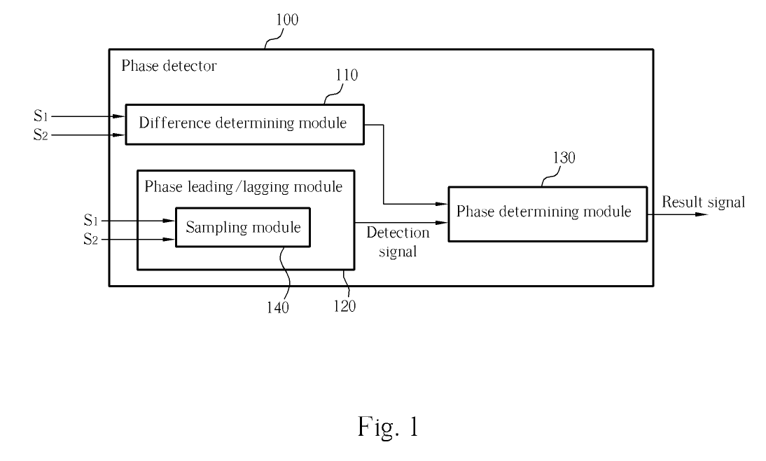

Please refer to FIG. 1, which is a functional block diagram of a phase detector 100 according to the present disclosure. As shown in FIG. 1, the phase detector 100 comprises a difference determining module 110, a phase leading/lagging determining module 120, and a phase determining module 130. The phase determining module 130 is electrically connected to the phase leading/lagging determining module 120 and the difference determining module 110.

In this embodiment, the difference determining module 110 and the phase leading/lagging determining module 120 both receive the two signals S1 and S2, but the difference determining module 110 and the phase leading/lagging determining module 120 performs different functions with these signals. That is, the difference determining module 110 determines the degree of the phase difference between the two signals S1 and S2. Here, the degree of the phase difference represents the “absolute value” of the phase difference. In other words, in this embodiment, the difference determining module 110 does not know the phase relationship (e.g., leading or lagging) between the two signals S1 and S2.

On the other hand, the phase leading/lagging determining module 120 is utilized to determine the phase relationship between the two signals S1 and S2. As shown in FIG. 1, the phase leading/lagging determining module 120 comprises a sampling module 140. In this embodiment, the sampling module 140 is utilized to sample the signal S2 at the rising edges of the signal S1. Therefore, the phase leading/lagging determining module 120 can determine whether the signal S1 leads the signal S2 according to the sampling result.

For example, the signal S2 can be sampled at the rising edge of the signal S1. If the signal S2 corresponds to logic level 1 at the rising edge of the signal S1, the phase leading/lagging determining module 120 determines that the signal S2 leads the signal S1. Conversely, if the signal S2 corresponds to logic level 0 at the rising edge of the signal S1, the phase leading/lagging determining module 120 determines that the signal S2 lags the signal S1 (or from another perspective: the signal S1 leads the signal S2). Surely, the phase leading/lagging determining module 120 can output a detection signal to the phase determining module 130 in order to notify the determining module 130 of the phase relationship.

As mentioned previously, the degree of the phase difference and the phase relationship are both determined. Therefore, the phase determining module 130 outputs a result signal according to the outputs of the difference determining module 110 and the phase leading/lagging determining module 120. That is, the result signal includes the information of the phase difference degree and the phase relationship. At this point, the operation of detecting the phase difference is completely performed.

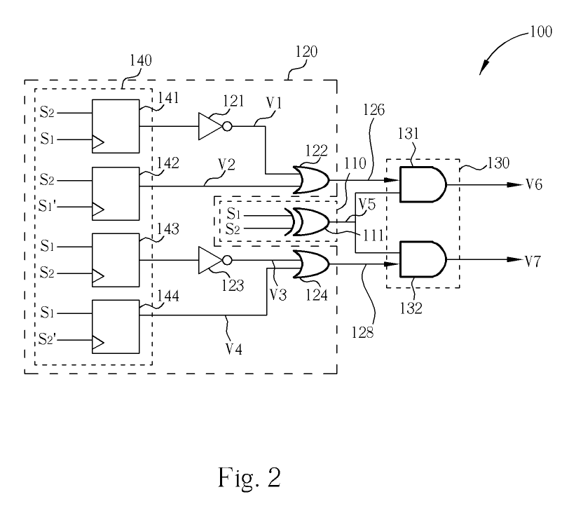

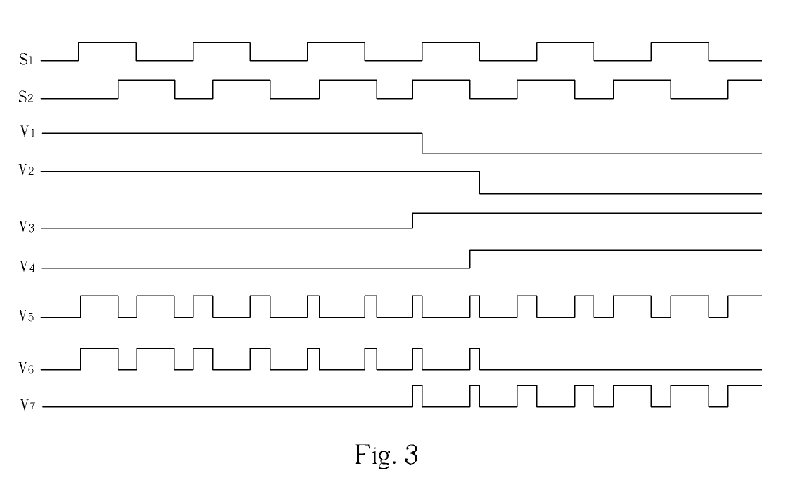

Please refer to FIG. 2 and FIG. 3. FIG. 2 is a diagram of the phase detector 100 of a first embodiment according to the present disclosure. FIG. 3 is a diagram of waveforms of signals shown in FIG. 2. As shown in FIG. 2, the phase detector 100 comprises a plurality of logic gates and flip-flops. The operation and function of the logic gates and the flip-flops will be illustrated in the following disclosure.

As shown in FIG. 2, the difference determining module 110 comprises an XOR logic gate 111, which receives the two signals S1 and S2. The XOR logic gate 111 performs an XOR operation upon the two signals S1 and S2. Therefore, in FIG. 3, the XOR logic gate 111 outputs a pulse if the two signals correspond to different logic levels (shown as the signal V5).

In one embodiment, the sampling module 140 comprises four D-type flip-flops 141, 142, 143, and 144, which respectively receive the two signals S1 and S2. Here, the D-type flip-flop 141 is illustrated first. The D-type flip-flop 141 utilizes the signal S1 to sample the signal S2. As is known, the signal S1 can be inputted into the CLK end of the D-type flip-flop 141 such that the signal S2 is sampled at the rising edges of the signal S1. Theoretically, the output signal of the D-type flip-flop 141 corresponds to 1 when the signal S2 corresponds to 1 at the rising edges of the signal S1. For the following utilization, the phase leading/lagging determining module 120 further comprises an inverter 121 (i.e., a NOT logic gate). The NOT logic gate 121 is utilized to invert the output of the D-type flip-flop 141. Therefore, in FIG. 3, if the signal S1 leads the signal S2, the signal V1, which is outputted by the NOT logic gate 121, corresponds to logic level 1, otherwise, the detection signal corresponds to the logic level 0.

Similarly, the D-type flip-flop 142 is utilized to perform the same function, except the signal S1′, which is an inverted signal of the signal S1, is inputted into the CLK end of the D-type flip-flop 142. Therefore, the operation of the D-type flip-flop 142 is to sample the signal S2 at the falling edges of the signal S1 (i.e., the rising edges of the inversed signal S1′). The output signal V2 (shown as the signal V2 in FIG. 3) corresponds to 1 when the signal S2 corresponds to 1 at the falling edges of the signal S1. Similarly, the output signal V2 can also be utilized to determine whether the signal S1 leads the signal S2.

In order to determine the phase relationship between the two signals S1 and S2, the signals V1 and V2 are both utilized. Therefore, the phase leading/lagging determining module further comprises an OR gate 122, coupled to the NOT logic gate 121 and the D-type flip-flop 142. The OR gate 122 outputs a detection signal, which is utilized to identify the phase relationship between the two signals according to the outputs of the NOT logic gate 121 and the D-type flip-flop 142. In this embodiment, when one of the signals V1 or V2 corresponds to 1, this means that the signal S1 leads the signal S2 such that the detection signal outputted by the OR logic gate 122 corresponds to 1.

Therefore, the phase leading/lagging relationship between the two signals S1 and S2 can be labeled by the detection signal. This result will be utilized by the phase determining module 130. From the above disclosure, the degree of the phase difference and the phase relationship are both determined. The aforementioned information will then be utilized by the phase determining module 130.

In this embodiment, the phase determining module 130 comprises an AND logic gate 131, which performs an AND operation on the detection signal 126 and the pulse outputted from the XOR logic gate 111. Therefore, the AND gate 131 outputs a result signal V6 shown in FIG. 3. The result signal V6 outputted by the AND gate 131 represents the phase difference when the signal S1 leads the signal S2.

On the other hand, the D-type flip-flops 143 and 144, the NOT logic gate 123, the OR logic gate 124, and the AND logic gate 132 are all utilized to identify the phase difference when the signal S1 lags the signal S2. They are symmetric to the above-mentioned D-type flip-flops 141 and 142, the NOT logic gate 121, the OR logic gate 122, and the AND logic gate 131. Furthermore, the operations are similar. For example, the signal S2 is inputted into the CLK end of the D-type flip-flop 143 and the inversed signal S2′ is inputted into the CLK end of the D-type flip-flop 144 such that the phase relationship can be determined and then the signals V3 and V4 are outputted. In other words, if the signal S1 lags the signal S2, the signals V3 and V4 of the D-type flip-flops 143 and 144 directly react to the phase relationship. Therefore, at last, the result signal V7 outputted by the AND gate 132 represents the phase difference when the signal S2 leads the signal S1.

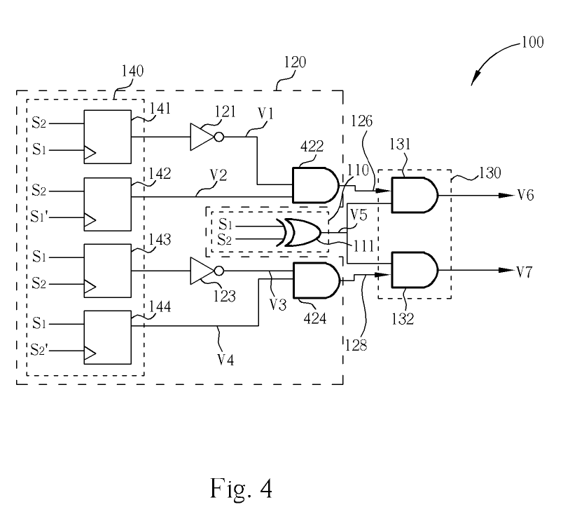

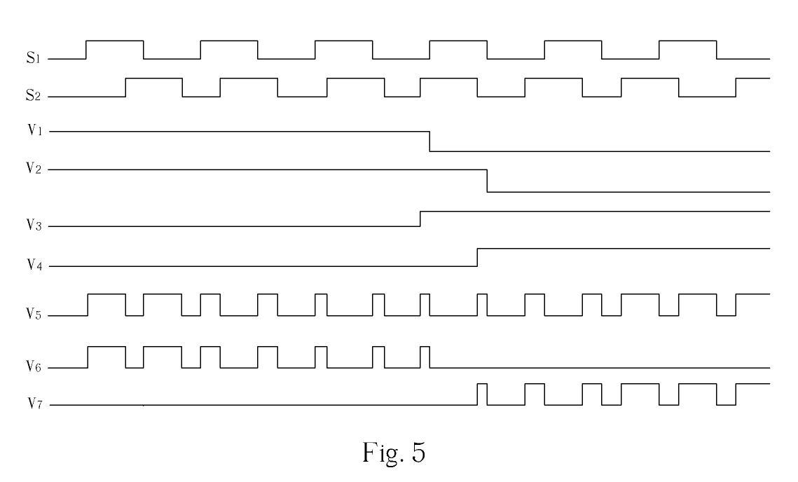

Please refer to FIG. 4 and FIG. 5. FIG. 4 is a diagram of the phase detector 100 of a second embodiment. FIG. 5 is a diagram of waveforms of signals shown in FIG. 4. As shown in FIG. 4, the phase detector 100 comprises a plurality of logic gates and flip-flops.

Primarily, in FIG. 4, the operations and the functions of the devices having the same number as the devices shown in FIG. 2 also perform similar functions. In this embodiment, the only difference is that AND logic gates 422 and 424 are utilized to replace the OR logic gates 122 and 124 shown in FIG. 2. Therefore, an AND operation is performed upon the outputs of the NOT logic gate 121 and the D-type flip-flop 142. In other words, in this embodiment, when the signals V1 and V2 both correspond to 1, this means that the signal S1 leads the signal S2 such that the detection signal 126 outputted by the AND logic gate 422 corresponds to 1. Otherwise, the detection signal 126 corresponds to 0. On the other hand, when the signals V3 and V4 both correspond to 1, this means that the signal S1 lags the signal S2 such that the detection signal 128 outputted by the AND logic gate 424 corresponds to 1. Otherwise, the detection signal 128 corresponds to 0.

Therefore, the AND logic gates 422 and 424 provide another method of determining the phase relationship between the two signals S1 and S2 instead of the OR gates 122 and 124. The difference results can be seen in the signals V6 and V7 shown in FIG. 2 and FIG. 4. Please refer to FIG. 2 and FIG. 4 again. In FIG. 2 and FIG. 4, as mentioned previously, the signal V6 shows the phase difference when the signal S1 leads the signal S2, and the signal V7 shows the phase difference when the signal S1 lags the signal S2. As it is shown, in FIG. 2, the signal V6 overlaps the signal V7. However, in FIG. 4, the signal V6 does not overlap the signal V7.

Furthermore, the circuits shown in FIG. 2 and FIG. 4 are only utilized as embodiments, not limitations of the present disclosure. Because the circuits shown in FIG. 2 and FIG. 4 are composed of logic gates and flip-flops, and the combination of logic gates can be equivalently replaced by other logic gates. For example, those skilled in the art can utilize Boolean algorithm to simulate other circuits such that the same result can be achieved. These changes also obey the spirit of the present disclosure.

In addition, the flip-flop is also utilized as a preferred embodiment, not a limitation. That is, the present disclosure can utilize other sampling circuits to sample the signal S1 (or the signal S2) at the edges of the signal S2 (the signal S1) such that the phase relationship can be determined. This change also obeys the spirit of the present disclosure.

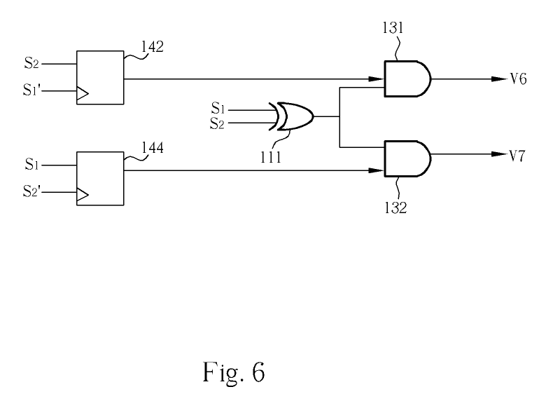

Surely, there is another way to determine the phase relationship. For example, in the case where the OR gates 122 and 124, and the AND gates 422 and 424 cannot be utilized, another method must exist. Please refer to FIG. 6, which is a diagram of the phase detector 100 of a third embodiment. In this embodiment, we can directly utilize the output of the D-type flip-flops 142 and 144 because they can react to the phase relationship. Similarly, the XOR gate 111 still determines the degree of the phase difference. Therefore, the voltage V6 and V7 respectively represents the leading/lagging phase difference.

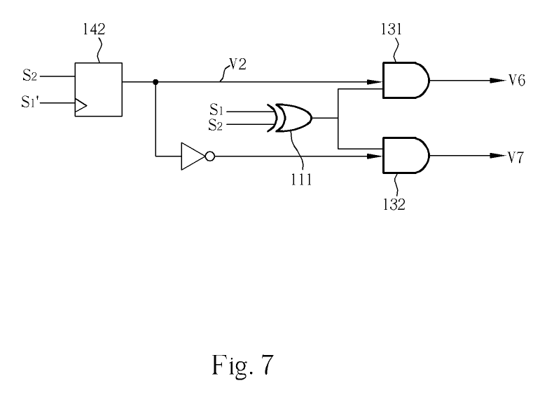

Furthermore, we can utilize only half of the circuits. Please refer to FIG. 7, which is a diagram of a phase detector of a fourth embodiment. In this embodiment, only the D-type flip-flop 142 is used. Since one of the D-type flip-flop 142 or 144 is sufficient to determine the phase difference. That is, if the D-type flip-flop 142 outputs a high logic level 1, this means that the signal S1 leads the signal S2. Otherwise, the signal S1 lags the signal S2. Similar to the above-mentioned embodiments, the voltages V6 and V7 can show the phase difference including the phase relationship and degree. Please note, although only the flip-flop 142 is used in FIG. 7, it is not a limitation of the disclosed invention. In other words, we can also utilize another flip-flop (e.g flip-flop 141, 143, or 144) to detect the phase relationship. This also obeys the spirit of the present invention. Compared with the fourth embodiment, the circuits shown in FIG. 2 and FIG. 4 are utilized because the circuits can reconfirm the phase relationship.

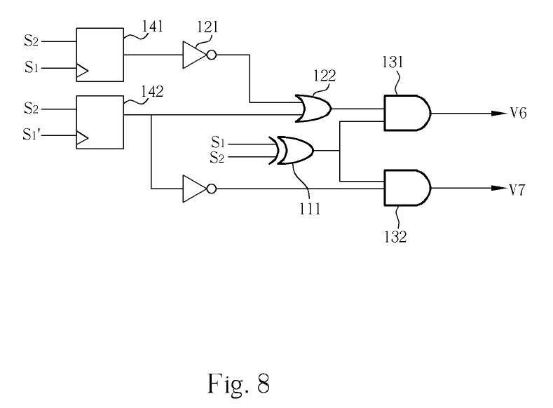

Surely, the operation of defining the phase relationship between the signal S1 and the signal S2 can be performed through two D-type flip-flops 141 and 142. please refer to FIG. 8, which is a diagram of a phase detector 100 of a fifth embodiment. As shown in FIG. 8, two D-type flip-flops 141 and 142 are utilized to detect the phase relationship. The operation of flip-flops 141 and 142 is omitted here because it has been illustrated in the above disclosure. Those skilled in the art could understand the function and operation of each device and the entire circuit.

As mentioned previously, the above-mentioned embodiments and related changes can be utilized according to different design choices. The circuits shown in FIG. 2, FIG. 4, FIG. 6, FIG. 7, FIG. 8 are only examples.

In the following disclosure, two input signals having glitches are utilized to illustrate the operation and the comparison of the circuits shown in FIG. 2 and FIG. 4.

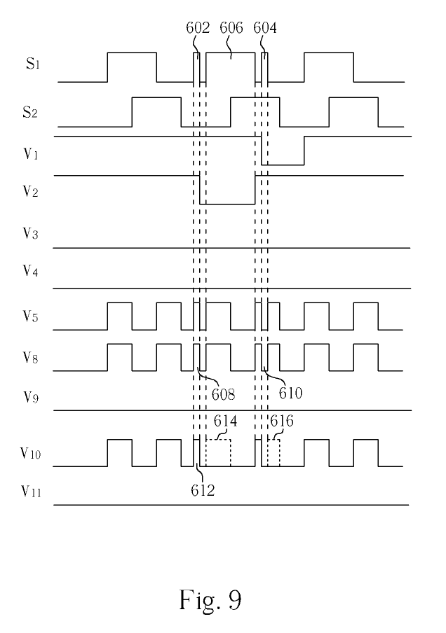

Please refer to FIG. 9, which is a diagram of waveforms where one of the input signals has glitches. As shown in FIG. 9, there are two glitches 602 and 604 appearing on both sides of a high-level duration 606 of the signal S1. The signals V8 and V9 respectively correspond to the signals V6 and V7 shown in FIG. 2. That is, signals V8 and V9 are the result signals when the signals S1 and S2 shown in FIG. 9 are inputted into the circuit shown in FIG. 2.

On the other hand, the signals V10 and V11 respectively correspond to the signals V6 and V7 shown in FIG. 4. That is, signals V10 and V11 are the result signals when the signals S1 and S2 shown in FIG. 9 are inputted into the circuit shown in FIG. 4. V8, V9, V10, and V11 are put together for the purpose of comparison.

When the circuit of FIG. 2 is used, a positive glitch 608 and a negative glitch 610 appear on the signal V8. The positive glitch 608 and the negative glitch 610 do not cause serious errors for the entire circuit because the area of the glitch 608 and the glitch 610 is not large.

On the other hand, when the circuit of FIG. 4 is used, a positive glitch 612 is generated and durations 614 and 616 disappeared. However, these errors (including the positive glitch 612 and vanished durations 614 and 616) are only encountered in a short period. That is, as shown in FIG. 9, there are no errors in the following waveform in the result signal V10. Both circuits shown in FIG. 2 and FIG. 4 can reduce the errors.

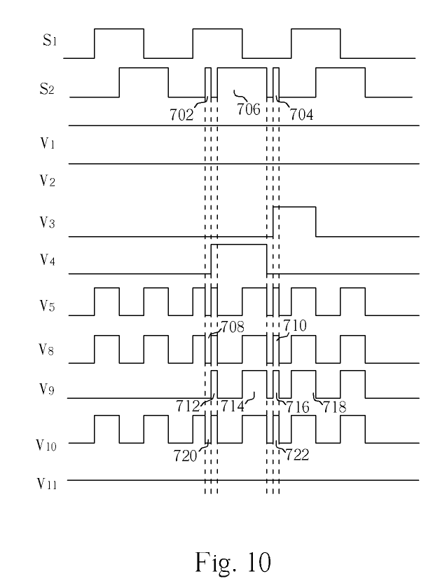

Please refer to FIG. 10, which is a diagram of waveforms where the other input signal has glitches. As shown in FIG. 10, there are two glitches 702 and 704 appearing on both sides of a high-level duration 706 of the signal S2. Similarly, The signals V8 and V9 respectively correspond to the signals V6 and V7 shown in FIG. 2. That is, signals V8 and V9 are the result signals when the signals S1 and S2 shown in FIG. 9 are inputted into the circuit shown in FIG. 2. And the signals V10 and V11 respectively correspond to the signals V6 and V7 shown in FIG. 4. That is, signals V10 and V11 are the result signals when the signals S1 and S2 shown in FIG. 9 are inputted into the circuit shown in FIG. 4.

When the circuit of FIG. 2 is used, a negative glitch 708 and a positive glitch 710 appear on the signal V8. Similarly, the negative glitch 708 and the positive glitch 710 do not cause serious errors for the entire circuit because the area of the glitch 708 and the glitch 710 is not so large. Furthermore, high-level durations 712, 714, 716, and 718 appear on the signal V9. Although the durations 712, 714, 716, and 718 are all errors, they do not cause continuous errors on subsequent signal V9.

When the circuit of FIG. 4 is utilized, only a negative glitch 720 and a positive glitch 722 are generated on the signal V10. Obviously, the errors are not serious. Because an XOR gate is used to determine the phase difference, the phase detector 100 is level-triggered, not pulse-triggered. A conventional phase detector using a pulse-triggered state machine can lead to false state transition if a glitch appears on an input signal, and therefore generate continuous errors. But the phase detector 100 determines the phase difference if the levels of the two signals are different. Therefore, errors caused by an pulse-triggered mechanism will not happen. Therefore, both circuits shown in FIG. 2 and FIG. 4 can reduce errors.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A phase detector for detecting a phase difference between a first signal and a second signal, the phase detector comprising:
a difference determining module, for outputting a pulse having a period in which a logic level of the first signal is different from a logic level of the second signal;
a phase leading/lagging determining module, for outputting a detection signal to identify a phase leading/lagging relationship between the first signal and the second signal; and
a phase determining module, for combining the pulse and the detection signal to output a result signal, wherein the result signal comprises difference and leading/lagging information between the first and the second signal.

2. The phase detector of claim 1, wherein the difference determining module is an XOR logic gate capable of performing an XOR logic operation upon the first and second signals to generate the pulse.

3. The phase detector of claim 1, wherein the phase leading/lagging determining module comprises:
a sampling module, for sampling the second signal at edges of the first signal;
wherein the phase leading/lagging determining module determines the detection signal according to a sampling result of the sampling module.

4. The phase detector of claim 3, wherein the sampling module comprises:
a first sampling unit, for sampling the second signal at rising edges of the first signal; and a second sampling unit, for sampling the second signal at falling edges of the first signal;
wherein the phase leading/lagging determining module determines the detection signal according to sampling results of the first and second sampling units.

5. The phase detector of claim 4, wherein the first and second sampling units are D-type flip-flops respectively triggered by rising edges of the first signal and falling edges of the first signal.

6. The phase detector of claim 4, wherein the phase leading/lagging determining module further comprises:
an inverter, coupled to the first sampling unit, for inverting the sampling result of the first sampling unit; and
an OR logic gate, coupled to the second sampling unit and the inverter, for performing an OR logic operation on the inverted sampling result of the first sampling unit and the sampling result of the second sampling unit to generate the detection signal.

7. The phase detector of claim 6, wherein the phase determining module comprises an AND logic gate, coupled to the OR logic gate of the sampling module and the difference determining module, for performing an AND logic operation upon the detection signal and the pulse to determine the phase difference.

8. The phase detector of claim 4, wherein the phase leading/lagging determining module further comprises:
an inverter, coupled to the first sampling unit, for inverting the sampling result of the first sampling unit; and
an AND logic gate, coupled to the second sampling unit and the inverter, for performing an AND logic operation on the inverted sampling result of the first sampling unit and the sampling result of the second sampling unit to generate the detection signal.

9. The phase detector of claim 8, wherein the phase determining module comprises an AND logic gate, coupled to the AND logic gate of the sampling module and the difference determining module, for performing an AND logic operation upon the detection signal and the pulse to determine the phase difference.

10. A phase detecting method for detecting a phase difference between a first signal and a second signal, the phase detecting method comprising:
outputting a pulse having a period in which a logic level of the first signal is different from a logic level of the second signal;
outputting an detection signal to identify a phase leading/lagging relationship between the first signal and the second signal; and
combining the pulse and the detection signal to output a result signal, wherein the result signal comprises difference and leading/lagging information between the first and the second signal.

11. The phase detecting method of claim, 10 wherein the step of outputting the pulse comprises:
performing an XOR logic operation upon the first and second signals to generate the pulse.

12. The phase detecting method of claim 10, wherein the step of outputting a detection signal comprises:
sampling the second signal at edges of the first signal; and
determining the detection signal according to a sampling result of the second signal at edges of the first signal.

13. The phase detecting method of claim 10, wherein the step of outputting a detection signal comprises:
sampling the second signal at rising edges of the first signal;
sampling the second signal at falling edges of the first signal;
determining the detection signal according to sampling results of the second signal at rising and falling edges of the first signal.

14. The phase detecting method of claim 13, wherein the step of determining the detection signal comprises:
inverting the result of sampling the second signal at rising edges of the first signal; and
performing an OR logic operation upon the inverted sampling result of sampling the second signal at rising edges of the first signal and the sampling result of sampling the second signal at falling edges of the first signal such that the detection signal is determined.

15. The phase detecting method of claim 14, wherein the step of determining the phase difference according to the pulse and the detection signal comprises:
performing an AND logic operation on the detection signal and the pulse to determine the phase difference.

16. The phase detecting method of claim 13, wherein the step of determining the detection signal comprises:
inverting the result of sampling the second signal at rising edges of the first signal; and
performing an AND logic operation upon the inverted sampling result of sampling the second signal at rising edges of the first signal and the sampling result of sampling the second signal at falling edges of the first signal such that the detection signal is determined.

17. The phase detecting method of claim 16, wherein the step of determining the phase difference according to the pulse and the detection signal comprises:
performing an AND logic operation upon the detection signal and the pulse to determine the phase difference.
